(19) United States
(12) Patent Application Publication
(10) Pub. No.: US 2003/0127727 A1
(43) Pub. Date: Jul. 10, 2003

(54) Thermally conductive sheet and semiconductor device using same

(75) Inventors: Ichiro Suehiro, Ibaraki-shi (JP); Noriaki Harada, Ibaraki-shi (JP); Yuji Hotta, Ibaraki-shi (JP)

Correspondence Address: LEYDIG VOIT & MAYER, LTD, TWO PRUDENTIAL PLAZA, SUITE 4900, 180 NORTH STETSON AVENUE, CHICAGO, IL, 60601-6780, US

(73) Assignee: Nitto Denko Corporation, Ibaraki-shi (JP)

(21) Appl. No.: 10/339,125

(22) Filed: Jan. 9, 2003

(30) Foreign Application Priority Data
Jan. 9, 2002 (JP) 2002-002379

(51) Int. Cl. H01L 23/34; B32B 15/04

(52) U.S. Cl. 257/712; 428/457

(57) ABSTRACT

The present invention provides a thermally conductive sheet that adheres finely to a semiconductor element and a heat dissipating plate, even with a low pressure at which a large-scaled semiconductor element cannot be broken, and that affords fine thermal conductivity, and a semiconductor device using this sheet. The thermally conductive sheet of the present invention has plural metal protrusions on at least one surface of a metal foil, wherein at least a part of gaps between the plural metal protrusions is filled with a resin, and the resin melts and/or fluidizes by heating and/or pressurizing to show an adhesion function. The semiconductor device of the present invention includes the above-mentioned thermally conductive sheet of the present invention and at least a semiconductor element and a heat dissipating plate adhered thereto.

### TECHNICAL FIELD OF THE INVENTION

The present invention relates to a thermally conductive sheet, which efficiently transmits the heat generated in a semiconductor element to a heat dissipating plate (thermal diffusion plate, heat spreader etc.), and a semiconductor device incorporating the same.

### BACKGROUND OF THE INVENTION

In achieving higher density and higher performance of semiconductor elements, an influence of the heat generated by semiconductor elements is a factor that narrows the extent of free design of semiconductor devices and electronic devices incorporating the semiconductor devices. As one means of reducing such influence of the heat, a method comprising efficiently transmitting the heat generated by a semiconductor element during operation to a heat dissipating plate on the outside of the semiconductor element via a thermally conductive sheet has been proposed. This method is expected to prevent high temperature of semiconductor elements and reduce malfunction at high temperatures.

As a conventional thermally conductive sheet, JP-A-6-291226 describes, for example, a heat dissipating sheet (thermally conductive sheet) comprising a cured product of a silicone resin composition containing a thermally conductive substance, which is laminated on one of or both surfaces of a metal foil. This sheet is superior in adhesion to a semiconductor element, but insufficient in thermal conductivity, and is unsuitable for use for a high-density semiconductor element that generates a large amount of heat.

As a different conventional art, the present inventors have proposed use of an anisotropic conductive film as a thermally conductive sheet (U.S. Pat. No. 6,245,175). This thermally conductive sheet is superior in thermal conductivity as compared to the thermally conductive sheet of the above-mentioned JP-A-6-291226. However, the anisotropic conductive film shows insufficient adhesion to semiconductor elements. This in turn poses a problem when a semiconductor element is large (e.g., one side being not less than 10 mm) because application of a pressure for adhesion causes breakage of the semiconductor element due to the stress concentration by the warp of the semiconductor element.

The problem of warp of semiconductor element becomes clear when the semiconductor element is large in size (one side being not less than 10 mm). While the degree of warp of the semiconductor element varies depending on the kind of the device, size thereof and thickness thereof, a semiconductor element having a side of 20 mm may show a warp of about 150 μm. There is a possibility that pressurization via a thermally conductive sheet (heat dissipating sheet) for adhesion of a warped semiconductor element to a heat dissipating plate may result in breakage of the semiconductor element due to the stress concentration by pressurization. Therefore, the pressurizing force is preferably not more than 1 MPa, generally about 0.5 MPa. For use for large semiconductor elements, therefore, a thermally conductive sheet affording sufficient adhesion to a semiconductor element and to a heat dissipating plate, even with such a low pressurizing force, has been demanded.

### SUMMARY OF THE INVENTION

The present invention has been made in view of such situation and aims at providing a thermally conductive sheet, which finely adheres to a semiconductor element and to a heat dissipating plate even with a low pressurizing force, that does not easily cause breakage of large semiconductor elements, and which affords fine thermal conductivity.

The present invention has the following characteristics.

(1) A thermally conductive sheet comprising plural metal protrusions disposed on at least one surface of a metal foil, wherein at least a part of gaps between the plural metal protrusions is filled with a resin, and the resin has an adhesion function when melted and/or fluidized by heating and/or pressurizing.

(2) The thermally conductive sheet of (1), comprising plural metal protrusions disposed on both surfaces of the above-mentioned metal foil.

(3) The thermally conductive sheet of (1) or (2), wherein the above-mentioned metal protrusions are made of a metal that softens at 150° C.-300° C. to form a metal junction with other metal.

(4) The thermally conductive sheet of any of (1) to (3), wherein the above-mentioned metal protrusions each have a shape of a column, a quadrangular prism or a sphere.

(5) The thermally conductive sheet of any of (1) to (4), wherein the above-mentioned metal protrusions are disposed on 20%-75% of the total area of both surfaces of the above-mentioned metal foil.

(6) A semiconductor device comprising at least a semiconductor element and a heat dissipating plate, which are adhered to each other via a thermally conductive sheet of any of (1) to (5).

(7) The semiconductor device of (6), wherein the above-mentioned heat dissipating plate is made of a metal, and at least a part of plural metal protrusions constituting the above-mentioned thermally conductive sheet and the heat dissipating plate form a metal junction.

### BRIEF DESCRIPTION OF THE DRAWINGS

FIG. 1 shows an outline of one embodiment of the thermally conductive sheet of the present invention, wherein FIG. 1(A) is a sectional view in the thickness direction of the sheet, and FIG. 1(B) and FIG. 1(C) each show a general view of the sheet from the directions I and II of FIG. 1(A).

FIG. 2 shows the outline of one embodiment of the thermally conductive sheet of the present invention, wherein FIG. 2(A) is a sectional view in the thickness direction of the sheet and FIG. 2(B) and FIG. 2(C) each show a general view of the sheet from the directions I and II of FIG. 2(A).

FIG. 3 shows the outline of the semiconductor device of the present invention.

In the Figures, 1 shows a thermally conductive sheet, 2 shows a metal foil, 3 shows a metal protrusion, 4 shows a resin, 5 shows a semiconductor element, 6 shows a heat dissipating plate and 7 shows a semiconductor device.

### DETAILED DESCRIPTION OF THE INVENTION

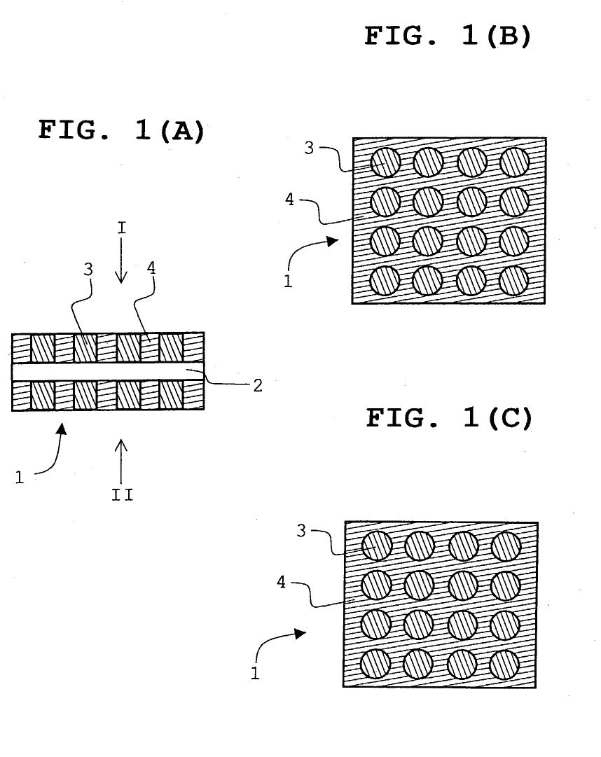

While the present invention relating to a thermally conductive sheet and a semiconductor element is explained by referring to drawings in the following, the present invention is not limited to the embodiments described in the drawings. As shown in FIG. 1, the thermally conductive sheet 1 of the present invention at least includes a metal foil 2, a metal protrusion 3 and a resin 4. These are sequentially explained below.

1. Metal Foil

While metal foil 2 known in the pertinent field can be used for the thermally conductive sheet 1 of the present invention, a copper foil is preferably used. This is because it facilitates the processing of the metal protrusion 3 to be mentioned blow. The metal protrusion 3 is generally formed by plating or etching. The use of copper foil as metal foil 2 facilitates application of conventional processes.

The thickness of metal foil 2 is generally selected from the range of 10 μm-100 μm in view of availability, cost and the like. In consideration of easy handling during formation of metal protrusion 3, the property of metal foil 2 itself to follow deformation and the like, it is preferably 20 μm-70 μm, more preferably 30 μm-40 μm.

The metal foil 2 combined with a metal protrusion 3 to be mentioned later contributes to the strikingly superior thermal conductivity of the thermally conductive sheet 1 of the present invention, as compared to conventional thermally conductive sheets. The action mechanism of the contribution is explained in detail in the explanation of metal protrusion 3 below.

2. Metal Protrusion

The metal protrusion 3 is disposed on at least one surface of the metal foil 2, preferably in plurality on both surfaces thereof.

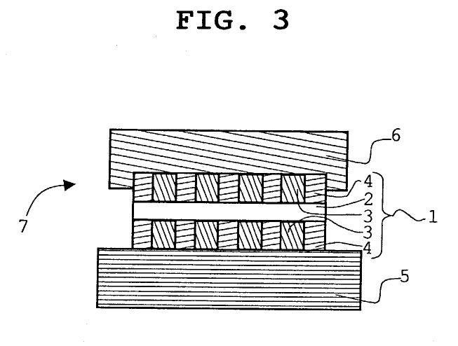

When the thermally conductive sheet 1 of the present invention is used, the surface of the top of the metal protrusion 3 comes to have a direct contact with the surface of a semiconductor element (i.e., heat element) 5 and/or heat dissipating plate 6 as shown in FIG. 3 to efficiently conduct the heat. To be specific, the heat generated in the semiconductor element 5 is transmitted to metal foil 2 via metal protrusion 3 that comes into contact with the semiconductor element 5, and spreads over the entire surface of metal foil 2. The heat that spread over the entire surface of the metal foil 2 is transferred to the entire surface of a heat dissipating plate 6. As a result, the topical generation of the heat in the semiconductor element 5 is efficiently dissipated from the entire surface of the heat dissipating plate 6. In this way, the thermally conductive sheet 1 of the present invention comprising a metal foil 2 and a metal protrusion 3 shows strikingly superior thermal conductivity as compared to conventional thermally conductive sheets, and improves the property (derived from metal foil 2) of the semiconductor element 5 to follow the warp.

In view of the above-mentioned action, therefore, the metal protrusion 3 is preferably disposed not only on one surface but both surfaces of the metal foil 2. Depending on the degree of heat generation of semiconductor element 5, cost and the like, however, it may be disposed only on one surface of the metal foil 2.

The shape of the metal protrusion 3 is not particularly limited and may be, for example, sphere, column, cone, quadrangular prism, cube and the like. Preferred are sphere and column in view of the thermal conductivity, processability and contact stability. As used herein, by the sphere is meant not only a complete sphere but also a metal protrusion 3 partly having a spherical surface (e.g., semi-sphere metal protrusion 3, metal protrusion 3 having a curved end surface and the like). When the metal protrusion 3 is a column or a quadrangular prism, the thickness thereof (diameter or length of one side) is generally 0.05-0.9 φ (or □) and the pitch (distance between the centers of adjacent metal protrusions 3) is 0.07 mm-1 mm, to achieve contact surface following property. The thickness is preferably 0.05-0.5 φ (or □) and the pitch is preferably 0.07 mm-0.6 mm, to more easily follow the contact surface. In the present specification, “φ” means the diameter of a circle and “□” means the length of one side of a square, both in millimeter according to JIS Z8317. The height of metal protrusion 3 is generally 10 μm-150 μm, preferably 50 μm-70 μm, because, when it is too low, it fails to sufficiently follow the difference in elevation of contact surface, which is created by warp, roughness and the like of heating surface (i.e., semiconductor element 5) and heat dissipating surface (i.e., heat dissipating plate 6), and when it is too high, the coefficient of thermal resistance becomes high.

The method for forming metal protrusion 3 is not particularly limited, and may be a process conventionally used for print circuit board and the like. Examples thereof include a process for selective removal of the surface of metal foil 2 by, for example, etching and the like to form metal protrusion 3, a process for forming metal protrusion 3 by selective plating of metal foil 2, and the like, a process for disposing a paste fluid containing solder and the like by screen printing and the like. For formation of metal protrusion 3 by plating, nickel plating, tin plating, copper plating, gold plating, solder plating and the like are used. In view of the property to follow warp of semiconductor element 5, tin plating, gold plating and solder plating that permit easily deformation by pressure are preferable.

More preferable embodiment of the material of metal protrusion 3 is a metal (solder, tin etc.) that softens at 150° C.-300° C. and is capable of forming a metal junction with other metal. As used herein, by the “other metal” is meant any metal that can be used for the heat dissipating plate 6 to be mentioned below and is not particularly limited. Examples thereof include copper, nickel and the like. When a thermally conductive sheet 1 having metal protrusion 3 made of such material and a metal heat dissipating plate 6 are used, the both are heated (further pressurized as necessary) to form a metal junction between them. Here, the metal junction means a weld junction, which is realized by general welding and the like. For metal junction, at least metal protrusion 3 needs to be melted, and heat dissipating plate 6 does not need to be melted. As a typical example of metal junction, a junction between a heat softened solder and a metal can be mentioned. By forming a metal junction, the contactability between heat dissipating plate 6 and thermally conductive sheet 1 is improved to enhance thermal conductivity.

The metal protrusion 3 preferably occupies 20%-75%, more preferably 35%-50%, of the surface area (total of both surfaces) of metal foil 2. The greater the proportion of the metal protrusion 3 is, the more the thermal conductivity is improved, and the smaller the proportion of the metal protrusion 3 is, the more easily it follows deformation such as warp of semiconductor element 5.

3. Resin

The resin 4 to be placed in the gap between metal protrusions 3 is a thermosetting resin or thermoplastic resin, which melts and/or fluidizes by heating and/or pressurizing to afford adhesion function. Here, heating and/or pressurizing means heating to 70° C.-250° C. and/or pressurizing to 0.5 MPa-1.0 MPa, and adhesion function means capability to adhere to other solid (i.e., semiconductor element 5, heat dissipating plate 6). Such resin 4 can adhere to semiconductor element 5 and heat dissipating plate 6 with a low pressure, and is expected to prevent damage of semiconductor element 5. When the adhesive property of resin 4 is sufficient, crimping is unnecessary, but in a contrary case, crimping may be used with a cramp disposed between semiconductor element 5 and heat dissipating plate 6.

Specific examples of the resin 4 to be used for the present invention include thermoplastic polyimide resin, epoxy resin, polyetherimide resin, polyamide resin, silicone resin, phenoxy resin, acrylic resin, polycarbodiimide resin, fluorine resin, polyester resin, polyurethane resin and the like.

The methods for placing resin 4 in the gap between metal protrusions 3 include, but not limited to, a method comprising applying a liquid resin 4 having low viscosity and flow property and scraping resin 4 above the surface of the top of metal protrusion 3 with a squeegee and the like to leave resin 4 in the gap alone, and a method comprising inserting a resin sheet having a volume sufficient to fill the gap between metal protrusions 3 into said gap, and heating and/or pressurizing to melt and/or fluidize resin 4 to bring metal protrusion 3 into contact with semiconductor element 5 and/or heat dissipating plate 6, thus penetrating the resin 4, whereby resin 4 adheres to the semiconductor element 5 and/or heat dissipating plate 6.

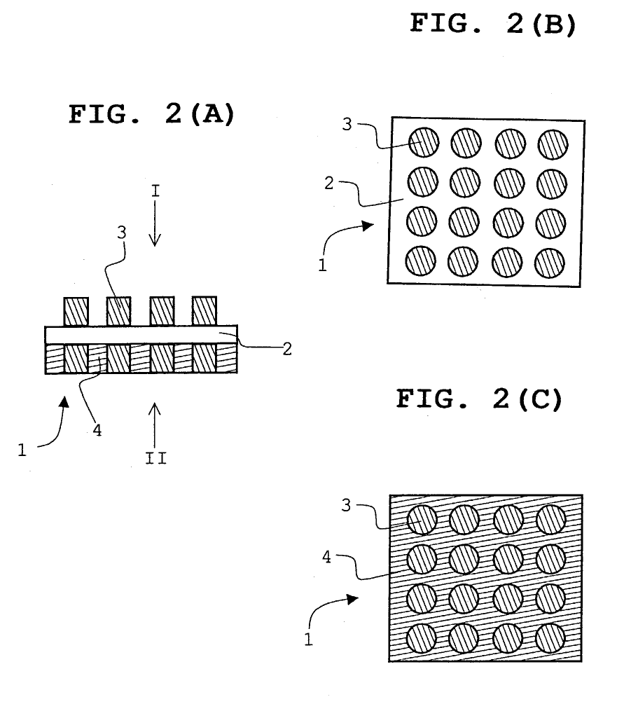

The resin 4 may fill all the gaps between plural metal protrusions 3 as shown in FIG. 1, or a part thereof as shown in FIG. 2. It is preferable that all the gaps on the surface of the thermally conductive sheet 1 that adheres to the semiconductor element 5 be filled with the resin in view of the improved adhesiveness. In contrast, the gaps on the surface that adheres to the heat dissipating plate 6 is not necessarily filled with resin 4, because sufficient adhesion (junction) tends to be obtained when the metal protrusion 3 and the heat dissipating plate 6 form a metal junction as mentioned above.

The adhesion between the thermally conductive sheet 1 obtained above, the semiconductor element 5 and the heat dissipating plate 6 can be achieved by the use of a known apparatus used for adhesion, such as flip chip bonder. As shown in FIG. 3, a semiconductor device 7, wherein the semiconductor element 5 and the heat dissipating plate 6 are adhered via thermally conductive sheet 1, can be obtained. The semiconductor device 7 may further contain other elements (heatsink, heat dissipating fan etc.) than the thermally conductive sheet 1, the semiconductor element 5 and the heat dissipating plate 6.

The shape and size of the semiconductor element 5 are not particularly limited, and the thermally conductive sheet 1 of the present invention can be easily applied to a large-sized semiconductor element 5 which easily gets broken by pressurization and to which conventional thermally conductive sheet and the like are difficult to apply. As used herein, a large-sized semiconductor element 5 means that it has an area of not less than 100 mm² (e.g., a square having a side of not less than 10 mm, preferably a square having a side of 15-25.4 mm).

### EXAMPLES

The present invention is explained in detail by referring to Examples, which are not to be construed as limitative.

### Example 1

The both surfaces of an electrodeposited copper foil (length 15 mm, width 15 mm and thickness 70 μm, Super HTE, Mitsui Mining and Smelting Co., Ltd.) as a metal foil 2 were etched (diameter 0.47 mm, pitch 0.6 mm, depth 20 μm) to form columnar metal protrusions 3 (bumps). By this treatment, metal protrusions 3 occupied 49% of the total surface area of the metal foil 2. A thermoplastic resin (polycarbodiimide resin 4, heat softening temperature 120° C., base concentration 32%, diluted with toluene) was flown between the bumps and the surface was scraped off with a squeegee. After filling the gaps between the bumps, the resin was heated at 120° C. for 1 min for curing. Then, the bump surface was exposed from the resin 4 by plane fine grinding to give a thermally conductive sheet 1. As shown in FIG. 3, the above-mentioned thermally conductive sheet 1 was sandwiched between a heat spreader (copper, thickness 1.5 mm, 20 mm square) as a heat dissipating plate 6 and a semiconductor element 5 (15 mm square), heated and pressurized at 230° C., 0.5 MPa for 20 sec.

The coefficient of thermal resistance of the thermally conductive sheet 1 itself was calculated by measuring the difference in temperature (Δt) between heating temperature of the semiconductor element 5 in the initial state and temperature transmitted to the heat spreader, which was found to be 0.12 cm² K/W. Then, a thermal shock test (125° C./−55° C., 30 min/30 min, 1 cycle) was repeated 1000 cycles and Δt was measured again, based on which the coefficient of thermal resistance was calculated. As a result, it was 0.13 cm² K/W, showing no difference between before and after the thermal shock test.

### Example 2

One surface of a copper foil (length 20 mm, width 20 mm and thickness 35 μm, Super HTE, Mitsui Mining and Smelting Co., Ltd.) as a metal foil 2 was half-etched (0.2 mm square, pitch 0.4 mm, depth 20 μm) to form quadrangular prism metal protrusions 3 (bumps). In addition, quadrangular prism metal protrusions 3 (0.2 mm square, pitch 0.4 mm, height 20 μm) were formed on the other side of this copper foil by pattern solder (Pb/Sn eutectic solder) plating. By this treatment, metal protrusions 3 occupied 25% of the total surface area of the metal foil 2. This copper foil, a heat dissipating plate 6 (heat spreader) as in Example 1 and a semiconductor element 5 were adhered as shown in FIG. 3 to allow adhesion of bumps formed by half-etching to the semiconductor element 5. When adhered, an adhesive sheet made of a 15 mm square, 10 μm thick polycarbodiimide resin 4 (heat softening temperature 150° C.) was inserted between the semiconductor element 5 and the copper foil, and between the copper foil and the heat spreader, and subjected to heating and pressurizing at 200° C., 0.5 MPa for 20 sec.

In the same manner as in Example 1, the coefficient of thermal resistance of the thermally conductive sheet 1 was calculated by measuring the difference in temperature (Δt) between the semiconductor element 5 and the heat spreader, which was found to be 0.08 cm² K/W. Then, a thermal shock test as in Example 1 was repeated 1000 cycles and Δt was measured again, based on which the coefficient of thermal resistance was calculated. As a result, it was 0.09 cm² K/W, showing no difference between before and after the thermal shock test.

### Example 3

A copper foil having bumps formed in Example 2 was inserted between heat spreader (copper, gold plated on surface, thickness 1.5 mm, 20 mm square) as a heat dissipating plate 6 and the semiconductor element 5 (same size as in Example 1) and heat-pressurized at 235° C., 0.5 MPa for 20 sec to allow adhesion of bumps formed by half-etching to the semiconductor element 5. The adhesive sheet as in Example 2 was inserted only in between the semiconductor element 5 and a copper foil and adhered and the bumps and the heat spreader between the heat spreader and the copper foil were metal joined without an adhesive sheet.

In the same manner as in Example 1, the coefficient of thermal resistance was calculated by measuring the difference in temperature (Δt) between the semiconductor element 5 and heat spreader, which was found to be 0.05 cm² K/W. Then, a thermal shock test as in Example 1 was repeated 1000 cycles and Δt was measured again, based on which and the coefficient of thermal resistance was calculated. As a result, it was 0.05 cm² K/W, showing no difference between before and after the thermal shock test.

### Example 4

One surface of a rolled copper foil (length 15 mm, width 15 mm, thickness 70 μm, TCU-O-70, Nippon Foil Mfg. Co., Ltd.) as a metal foil 2 was etched (diameter 0.47 mm, pitch 0.6 mm, depth 30 μm) to form columnar metal protrusions 3 (bumps). On the other side of this copper foil at the same position of the bump (exactly on the back), solder bumps (height 100 μm) having the same diameter and pitch as the aforementioned were formed. By this treatment, metal protrusions 3 occupied 49% of the total surface area of the metal foil 2. On the side of the copper foil where bumps were formed by etching was flown a thermoplastic resin (polycarbodiimide resin, heat softening temperature 120° C., base concentration 32%, diluted with toluene), and the surface was scraped off with a squeegee. After filling the gap between the bumps, the resin was heated at 120° C. for 1 min for curing. Then, the bump surface was exposed from the resin 4 by plane fine grinding to give a thermally conductive sheet 1. This thermally conductive sheet 1 was inserted between a heat spreader (copper, thickness 1.5 mm, 20 mm square) as a heat dissipating plate 6 and a semiconductor element 5 (same size as in Example 1), heated and pressurized at 240° C., 0.5 MPa, 20 sec to allow adhesion of a bump formed by etching to the semiconductor element 5. Between the heat spreader and the copper foil (surface where solder bump was formed), bump and heat spreader were metal joined.

In the same manner as in Example 1, the coefficient of thermal resistance of the thermally conductive sheet 1 was calculated by measuring the difference in temperature (Δt) between the semiconductor element 5 and the heat spreader, which was found to be 0.12 cm² K/W. Then, a thermal shock test as in Example 1 was repeated 1000 cycles and Δt was measured again, based on which the coefficient of thermal resistance was calculated. As a result, it was 0.13 cm² K/W, showing no difference between before and after the thermal shock test.

### Example 5

On both surfaces of a rolled copper foil (TCU-O-35, Nippon Foil Mfg. Co., Ltd.) as a metal foil 2 were formed quadrangular prism metal protrusions 3 (bumps of Pb/Sn eutectic solder, 0.43 mm square, pitch 0.6 mm, height 100 μm) by screen printing. The position of the bumps was the same as that of the bumps on the other side. By this treatment, metal protrusions 3 occupied 61% of the total surface area of the metal foil 2. On one side of the metal foil 2 was laminated a solder resist and on the opposite side was adhered a 10 μm thick adhesive sheet made from a polycarbodiimide resin 4 (heat softening temperature 150° C.). Then, the bump surface was exposed from the resin 4 by plane fine grinding to give a thermally conductive sheet 1. This thermally conductive sheet 1 was inserted between a heat spreader (copper, thickness 1.5 mm, 20 mm square) as a heat dissipating plate 6 and a semiconductor element 5 (same size as in Example 1), heated and pressurized at 240° C., 0.5 MPa for 20 sec to allow adhesion of the surface, to which the adhesive sheet had been adhered, to the semiconductor element 5. By this adhesion, the solder bumps show improved property to follow the semiconductor element surface. The heat spreader and the solder bumps were metal joined.

In the same manner as in Example 1, the coefficient of thermal resistance of the thermally conductive sheet 1 was calculated by measuring the difference in temperature (Δ) between the semiconductor element 5 and the heat spreader, which was found to be 0.08 cm² K/W. Then, a thermal shock test as in Example 1 was repeated 1000 cycles and Δt was measured again, based on which the coefficient of thermal resistance was calculated. As a result, it was 0.09 cm² K/W, showing no difference between before and after the thermal shock test.

### Comparative Example 1

A thermally conductive sheet (thickness 0.5 mm) filled with a commercially available silicone resin containing high thermally conductive filler (alumina) in a volume ratio of 70% was sandwiched between a semiconductor element and a heat spreader as shown in Example 1. The entire laminate was heat-pressurized at 160° C., 0.5 MPa for 3 sec. The difference in temperature (Δt) was measured between the semiconductor element 5 in the initial state and the heat spreader to determine coefficient of thermal resistance, which was about 1.5 cm² K/W. The thermally conductive sheet was strikingly inferior to the thermally conductive sheets of Examples 1-5 in thermal conductivity.

### Comparative Example 2

A thermally conductive paste obtained by adding a silicon nitride superfine filler to a commercially available silicone resin in a weight ratio of 80% was applied in a thickness of about 0.1 mm to deal with the warp of a semiconductor element, and the paste was sandwiched between a semiconductor element and a heat spreader as shown in Example 1. The Δt in the initial state was measured and the coefficient of thermal resistance was determined, which was about 0.15 cm² K/W. Then, a thermal shock test as in Example 1 was repeated 1000 cycles. As a result, the paste was observed to have flown outside. The Δt was measured again, based on which the coefficient of thermal resistance was calculated. As a result, it was 0.6 cm² K/W, showing degradation of conductivity.

The thermally conductive sheet 1 of the present invention (1) easily follows deformation, such as warp and the like of semiconductor element 5, because the sheet includes resin 4 and metal foil 2, (2) shows improved adhesion to the semiconductor element 5 and heat dissipating plate 6 due to the adhesion function of the resin 4 upon heating and/or pressurizing, (3) can efficiently conduct heat due to the presence of metal protrusion 3, and (4) can spread a topically generated heat over the entire surface by the presence of the above-mentioned metal foil 2. Therefore, the thermally conductive sheet 1 of the present invention can adhere even in the case of adhesion to a large-sized semiconductor element 5, with a low pressure that does not cause breakage of the semiconductor element 5, by the action of the above-mentioned (1) and (2), and after adhesion, can conduct the heat generated during operation of the semiconductor element 5 efficiently to the heat dissipating plate 6 due to the action of (3) and (4). In a preferable embodiment of the present invention, the metal protrusion 3 and the heat dissipating plate 6 can form a metal junction. As a result, the adhesive property (junction property) and thermal conductivity can be improved. The semiconductor device 7 having such thermally conductive sheet 1 can reduce the problem of heat generated by the semiconductor element 5. Accordingly, the use of semiconductor device 7 of the present invention is expected to extend the degree of free design of the circuit of electronic devices.

This application is based on a patent application No. 2379/2002 filed in Japan, the contents of which are hereby incorporated by reference.

The references cited herein, including patents and patent applications, are hereby incorporated in their entireties by reference, to the extent that they have been disclosed herein.

What is claimed is:

1. A thermally conductive sheet comprising plural metal protrusions disposed on at least one surface of a metal foil, wherein at least a part of gaps between the plural metal protrusions is filled with a resin, and the resin has an adhesion function when melted and/or fluidized by heating and/or pressurizing.

2. The thermally conductive sheet of claim 1, comprising plural metal protrusions disposed on both surfaces of said metal foil.

3. The thermally conductive sheet of claim 1, wherein said metal protrusions are made of a metal that softens at 150° C.-300° C. to form a metal junction with other metal.

4. The thermally conductive sheet of claim 1, wherein said metal protrusions each have a shape of a column, a quadrangular prism or a sphere.

5. The thermally conductive sheet of claim 1, wherein said metal protrusions are disposed on 20%-75% of the total area of both surfaces of said metal foil.

6. A semiconductor device comprising at least a semiconductor element and a heat dissipating plate adhered via the thermally conductive sheet of claim 1.

7. The semiconductor device of claim 6, wherein said heat dissipating plate is made of a metal, and at least a part of plural metal protrusions constituting said thermally conductive sheet and the heat dissipating plate form a metal junction.
